(19) United States
(12) Patent Application Publication
(10) Pub. No.: US 2023/0288953 A1
(43) Pub. Date: Sep. 14, 2023

(54) ADJUSTABLE CLOCK PHASE FOR PEAK-CURRENT REDUCTION

(71) Applicant: OPPSTAR TECHNOLOGY SDN BHD, Bayan Lepas (MY)

(72) Inventors: Kim Pin Tan, Jelutong (MY); Hun Wah Cheah, Batu Mauang (MY)

(21) Appl. No.: 17/690,411

(22) Filed: Mar. 9, 2022

(51) Int. Cl. G06F 1/10; G06F 1/08

(52) U.S. Cl. CPC G06F 1/10; G06F 1/08

(57) ABSTRACT

Circuit devices, configurable circuit devices, and methods of configuring the same include a first logic block and a routing block. The routing block routes a clock signal to the first logic block and includes a selectable delay circuit with delay paths and a multiplexer that selects one of the delay paths. Each of the delay paths delays the clock signal by a different amount.

### BACKGROUND

### Technical Field

Described herein are embodiments related to field programmable gate arrays (FPGAs), and, more particularly, adjustable clock phase circuitry that reduces peak current across a device.

### Description of the Related Art

FPGAs are a type of reconfigurable circuit, which permits rapid deployment of new circuit designs to hardware. Pre-built clock networks run across the device, providing clocks for sequential registers. These clock networks are often designed to minimize skew, which can result in the sequential registers switching at roughly the same time.

### SUMMARY

A circuit device includes a first logic block and a routing block. The routing block routes a clock signal to the first logic block and includes a selectable delay circuit with delay paths and a multiplexer that selects one of the delay paths. Each of the delay paths delays the clock signal by a different amount.

A method of configuring a circuit device includes placing and routing circuit design components, including a first logic block, a second logic block. The first logic block and the second logic block each receive a clock signal. A first phase delay path for the clock signal to the first logic block is selected and a second phase delay path for the clock signal to the second logic block is selected. The first phase delay path and the second phase delay path have different delay times, to cause the first logic block and the second logic block to trigger out of phase.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a block diagram of a field programmable gate array (FPGA) device that includes a fabric of configurable blocks and routing blocks, in accordance with an embodiment of the present invention;

FIG. 2 is a circuit schematic that illustrates clock routing with selectable delay paths to decrease peak current consumption in downstream logic blocks, in accordance with an embodiment of the present invention;

FIG. 3 is a circuit schematic that illustrates a configuration of a selectable clock delay, with a delayed clock signal being applied at one point in a data path, in accordance with an embodiment of the present invention;

FIG. 4 is a circuit schematic that illustrates a configuration of a selectable clock delay, with a delayed clock signal being applied at one point in a data path, in accordance with an embodiment of the present invention; and

FIG. 5 is a block/flow diagram of a method of configuring a field programmable gate array (FPGA) to reduce peak power, in accordance with an embodiment of the present invention.

### DETAILED DESCRIPTION

A field programmable gate array (FPGA) may include a number of different programmable elements. For example, logic elements and memory may be connected to one another by configurable routing connections, making it possible to implement arbitrary circuits within certain resource constraints. Clock networks run across the FPGA to provide clock information for a variety of devices, including sequential registers. When the clock network provides signals to target devices roughly simultaneously, known as having a low “skew,” the target devices may be triggered at roughly the same time. As a result, those devices may draw current at the same time, resulting in a relatively high peak current.

This high peak current can have detrimental effects on the device’s operational characteristics. For one, the device will need to be able to supply larger amounts of current to accommodate the peak draw. For another, the large amounts of current can increase the amount of electromagnetic interference caused by the device, resulting in additional noise that needs to be shielded. Further, the large current draw can cause the power supply voltage to drop.

An FPGA may include delay circuitry in its routing blocks. This delay circuitry may provide different amounts of delay to different clock paths, thereby preventing the simultaneous switching of the sequential registers. By causing the sequential registers to trigger out of phase from one another, the number of devices that are switching at any one time is decreased, and the peak current is reduced.

To accomplish this, the circuit design that is to be implemented by the FPGA may be analyzed and the clock phases of the different clock paths may be set to distribute clock switching activities over time in a given region. This analysis may take into account the clock phase of receiving registers versus launching registers to preserve the timing of certain paths, so that the clock skew that is introduced does not affect the maximum device frequency or cause hold time violations.

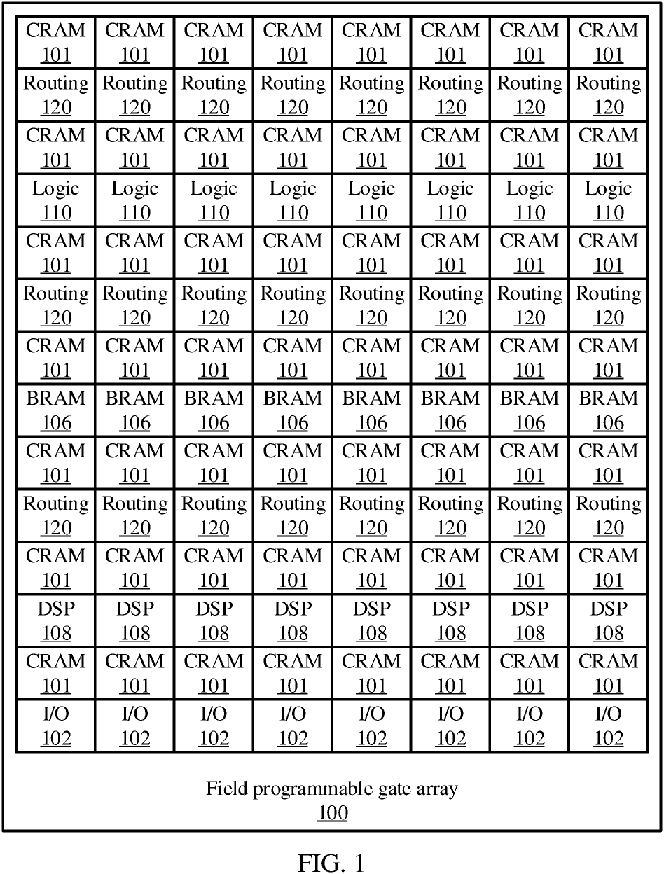

Referring now to FIG. 1, a block diagram of an illustrative embodiment of an FPGA 100 is shown. The FPGA 100 includes a fabric of configurable logic blocks 110. Although the fabric 100 is shown with a certain number of logic blocks 110, it should be understood that any appropriate number of logic blocks 110, and other ancillary blocks, may be used. These logic blocks 110 represent hardware components that perform logic operations which may be defined at run-time, according to hardware definition instructions. For example, the logic blocks 110 may include lookup tables LUTs that perform arbitrary computations, and may include further components, such as registers, digital logic, multiplexers, and other transistors. The logic blocks 110 may have a relatively simple internal structure, with complex operations being performed by connecting multiple logic blocks 110 using configurable interconnects. The logic blocks 110 may also have a relatively complex internal structure, with specific functions being performed according to internal configurations of the logic blocks 110. The logic blocks 110 may have differing internal structures, in accordance with the configuration of the FPGA 100. Input/output (I/O) blocks 102 provide inputs and outputs to the fabric of logic blocks 110.

The functions of the FPGA 100 may be configured at start-up, and may further be reconfigured or partially reconfigured during runtime. Thus, logic blocks 110 may be initialized with a first function when the device is powered up, and may later be reconfigured to perform different functions, for example responsive to an error or changing operational conditions.

Other components of the FPGA 100 may perform specific, hardwired functions. For example, a transceiver may provide communications with off-chip devices, block random access memory (BRAM) 106 may provide dedicated on-die data storage, and digital signal processor (DSP) 108 may provide complex signal computations. While these functions could be performed using circuitry that is implemented in the fabric of logic blocks 110, the inclusion of dedicated hardware components for common functions maximizes the available space for implementing user designs. Any appropriate functions may be implemented in this manner, beyond BRAM and DSP functions. Further, it should be understood that the relative positioning of I/O blocks 102, logic blocks 110, BRAM blocks 106, and DSP blocks 108 that is shown in FIG. 1 is purely exemplary and should not be interpreted as limiting, and that any appropriate number and placement of such blocks may be used instead.

Each block may have a respective configuration random access memory (CRAM) 101, which provides configuration information for the block. In the case of a logic block 110, for example, the associated CRAM 101 may store information that determines the output values of any lookup tables in the logic block 110, as well as any other configuration information that may be needed to perform the logic block’s function.

The configuration of the FPGA 100 uses routing blocks 120 to direct signals from one functional block to the next. The routing blocks 120 may include one or more multiplexers which can selectively pass signals to any appropriate neighboring block. The routing blocks 120 may have associated CRAMs 101 as well, which may store information that is used to determine the routing performed by the routing blocks 120. In this manner, a signal that originates in one block can be routed to any arbitrary destination block in the fabric 100. Signals propagating through the routing blocks 120 incur a certain amount of delay. This delay along clock paths may be adjusted to cause the signals to arrive when needed, for example to reduce clock skew or to reduce peak current consumed by a set of target devices.

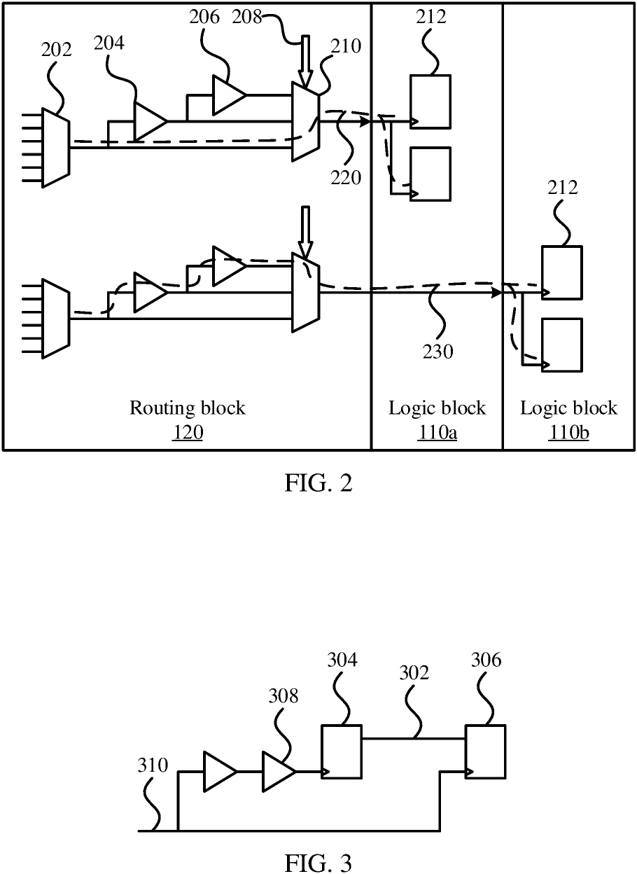

Referring now to FIG. 2, an exemplary phase selection circuit for a routing block is shown. A routing block 120 passes clock information to a first logic block 110a and a second logic block 110b. Data paths within the routing block 120 are omitted for the sake of simplicity, but it should be understood that any appropriate routing and configuration circuitry may be present within the routing block 120.

A first multiplexer 202 selects an appropriate input clock signal. These input clock signals may vary according to, e.g., frequency and/or phase. The phase selection circuitry includes three different paths to a second multiplexer 210. The second multiplexer is controlled by a control signal 208 which may be set, for example, by CRAM 101. Although three delay paths are shown, it should be understood that any appropriate number of delay paths may be used.

A first delay path may have no delay stages, and the additional delay paths may include one or more delay stages. It is specifically contemplated that each delay path may have a different number of delay stages from the other delay paths feeding a given logic block 110, such that each delay path will cause a different signal propagation delay.

For example, a first delay path may include zero delay stages, a second delay path may include a first delay stage 204, and third delay path may include the first delay stage 204 and a second delay stage 206. The delay stages may be formed by pairs of inverters. Each pair of inverters will first invert, and then revert, an input signal, so that the output of the delay stage will have the same value as the input, but will be delayed according to the amount of time it takes the signal to propagate through the delay stage. The delay time of a delay stage may be extended by adding additional pairs of inverters, thereby multiplying the delay.

Configuration of the delay paths may be performed during FPGA compilation, when the output values of the CRAM 101 are determined. The stored value in the CRAM 101 may be output to the second multiplexer 210 to control which of the different delay paths is used. For example, if the second multiplexer 210 selects between three or four delay paths, then a two-bit selection signal 208 is supplied by the CRAM 101. In this manner, the phase shift can be bypassed and turned off when not being used, or when a clock phase shift is not needed.

The logic blocks 110a and 110b are shown with respective registers 212, which receive clock signals from the routing block 120. Any appropriate number of logic blocks 110 may receive clock signals from a given routing block 120, and each may be set with a different phase shift according to a respective selected delay path. Identical delay circuitry is shown for each of the logic blocks, but it should be understood that different delay circuitry may be used for each, for example implementing different numbers of possible delay paths.

Thus, the first logic block 110a is shown with a first delay path 220 and the second logic block 110b is shown with a second delay path 230. The first delay path 220 passes from the respective first multiplexer 202 to the respective second multiplexer 210 without passing through any delay stages and therefore reaches the first logic block 110a relatively quickly. The second delay path 230 passes from the respective first multiplexer 202 to the respective second multiplexer 210 after passing through both the first delay stage 204 and the second delay stage 206. Thus, signals passing through the second delay path 230 take longer to reach the registers 212 of the second logic block 110b than the signals passing through the first delay path 220. Assuming the clock signals leaving the first multiplexers 202 start in phase, the registers 212 of the respective logic blocks 110 will then be triggered out of phase from one another, so that the peak current is decreased.

As device sizes continue to scale down, transistor device geometry tends to decrease faster than interconnect sizes. As a result, the area consumed by routing multiplexers in an FPGA is generally dominated by the metal interconnects, rather than by transistor size. As a result, the addition of transistors to implement the delay stages 206 and the second multiplexers 210 does not significantly impact the area consumed by the routing blocks 120.

Referring now to FIG. 3, a first data path is shown, with a delay path being applied. In a first data path 302, information is transmitted from a first register 304 to a second register 306. When the clock input of the first register 304 is triggered, the output of the first register 304 may update and forms an input to the second register 306. In this case, the first data path 302 is relatively simple, for example with data being communicated directly from the first register 304 to the second register 306.

In this particular example, the hold time of the second register 306 may be particularly sensitive. Hold time may be understood as the amount of time, after a clock’s active edge, in which the data input to a register needs to be stable for the register to reliably reproduce it as an output. In this case, the clock phase shift may be applied to the clock signal input of the first register 304 using the delay stage(s) 308. In this way, the triggering of the first register 304 is delayed to increase the likelihood that the input to the second batch 306 is stable for the duration of the hold time.

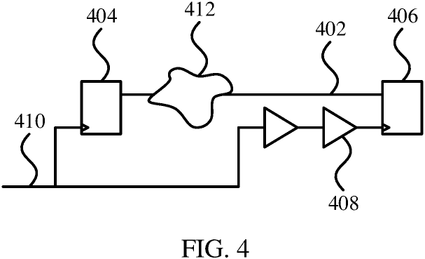

Referring now to FIG. 4, a second data path is shown, with a delay path being applied. In a second data path 402, information is transmitted from a first register 404 to a second register 406. When the clock input of the first register 404 is triggered, the output of the first register 404 may update and forms an input to the second register 406. In this case, the second data path 402 includes a long data path 412 which may incur a relatively long signal propagation delay. For example, the first register 404 and the second register 406 may be distant from one another in the device, or there may be additional devices included that cause their own respective delays.

In this particular example, due to the long data path 412, adding additional delay to the clock path of first register 404 could delay downstream processing and decrease the maximum frequency of the device. The maximum frequency of the path is determined by the clock period, the delay of the data path, and clock skew, where clock period is the inverse of the clock frequency, data delay is a combination of the delays of the first register 404, the delay of the data path 402, the delay of any additional contributions 412 on the data path 402, and an intrinsic setup time of the second register 406. The clock skew may be determined by a clock delay of the first register 404 and a clock delay of the second register 406. The data from the first register 404 needs to be stable before triggering the next clock edge of the second register 406. Adding clock delay to the clock of the first register 404 reduces the setup time margin or may violate setup time. Adding delay to the clock of the second register 406 ensures that the maximum frequency is not affected (e.g., if the first register 404 also has delay added to its clock) or may possibly be improved (e.g., if no clock delay is added to the first register 404).

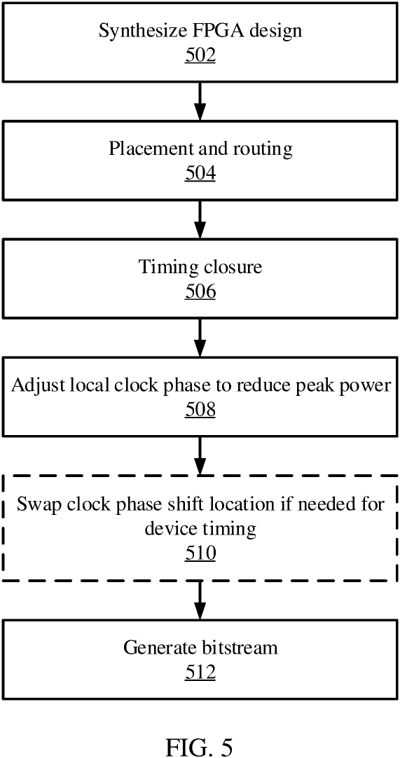

Referring now to FIG. 5, a method of generating a design for an FPGA device is shown. Block 502 synthesizes an FPGA design from a high-level design. For example, the design may be defined using a hardware description language (HDL) that is suitable for use with an FPGA device. The HDL identifies functional relationships between components, and block 502 turns this HDL design into a set of hardware components and connections that may be used to implement the function. For example, the synthesis may output a set of lookup tables, logic devices, and memory devices.

Block 504 performs placement and routing, providing a layout for the synthesized components on the FPGA device. For example, this device may implement particular logic blocks 110 and routing blocks 120, with corresponding CRAM 101, to implement the design. Routing may include configuring the routing blocks 120 to route the data and clock signals in the manner determined by the synthesis. Notably, the routing blocks 120 may include selective phase shift circuitry, as described above, to control clock phases.

Block 506 performs timing closure, which ensures that timing-sensitive operations receive the proper inputs. For example, critical paths may be identified, which represent paths where data signal delays exceed the clock cycle delay, or the path having the largest delay. The design may be modified to reduce the time of particular paths to ensure that all timing requirements are met.

Block 508 makes adjustment to local clock phases to reduce the peak power consumed, by reducing the number of components that are triggered at the same time. As described above, this adjustment may be performed by configuring selectable delay lines within the routing multiplexers 120, so that different clock paths are delayed by different amounts. These selections may be set in the CRAM 101 corresponding to a given routing block 120. The CRAM 101 provides selection inputs 208 to the respective second multiplexer(s) 210 to select a given delay path with an appropriate number of delay stages.

Block 508 may determine the placement of all sequential cells in the design, for example including flip-flops and sequential registers in logic blocks 110 and in any other blocks, such as blocks with a predetermined set purpose. Based on the placement of the sequential cells, block 508 may select clock paths such that, for a particular local area, a first percentage of the cells may be triggered by a faster clock and a second percentage of the cells may be triggered by a slower clock. In some cases, multiple different phase shift lengths are used, to create more than three or more sets of cells. Block 508 further performs this phase shifting across the various regions of the FPGA device, so that a similar percentage of cells are triggered with the different respective delays at both a local level and a global level. The regions of the FPGA device may be defined based on a simulation of power/ground IR drop or electromagnetic interference. Local reduction of peak current levels ensures that no local hot spots are formed.

Block 510 optionally swaps clock phase shift locations, for example based on the timing information determined in block 506. For example, if a selected phase delay on a particular clock path would result in a hold time violation or a decrease in maximum device frequency, then block 210 may move the phase shift to a different point along the clock path, where the timing problem would not occur.

For example, block 510 may determine setup time and hold time for cells to determine timing critical paths. For example, timing paths with a timing margin less than a certain clock delay may be considered timing critical. For setup time critical paths, where the setup time of a cell affects the proper operation of the FPGA device, block 510 may check whether an added clock phase delay will degrade the maximum frequency. If so, then block 510 may change the position of the delay path from the launching sequential cell to the receiving sequential cell to ensure that maximum frequency is not affected.

Block 512 generates a bitstream from the finalize design. The bitstream includes information that programs the actual FPGA device. When executed by the FPGA device, the bitstream is executed to implement the design within the FPGA’s hardware. The bitstream may be stored in a memory on the FPGA device and may be executed when the FPGA device is powered on.

As described herein, programmable logic devices (PLDs) are a type of integrated circuit that can be programmed to perform specified logic functions. One type of PLD, the FPGA, may include an array of programmable tiles. These programmable tiles can include, for example, input/output blocks (IOBs), configurable logic blocks (CLBs), BRAMs, multipliers, DSP data path elements or blocks, processors, clock managers, delay lock loops (DLLs), and so forth.

Each programmable tile may include both programmable interconnect and programmable logic. The programmable interconnect may include a large number of interconnect lines of varying lengths, interconnected by programmable interconnect points (PIPs), which may be configured to connect various circuit components in accordance with their operational relationships. The programmable logic implements the logic of a user design using programmable elements that can include, for example, function generators, registers, arithmetic logic, and so forth.

The programmable interconnect and programmable logic may be initialized by loading a stream of configuration data into internal configuration memory cells that define how the programmable elements operate. The configuration data can be read from memory (e.g., from an external programmable read only memory (PROM)) or written into the FPGA by an external device. The collective states of the individual memory cells then determine the function of the FPGA.

Another type of PLD is the Complex Programmable Logic Device (CPLD). A CPLD includes two or more “function blocks” connected together and to input/output (I/O) resources by an interconnect switch matrix. Each function block of the CPLD may include a two-level AND/OR structure similar to those used in Programmable Logic Arrays (PLAs) and Programmable Array Logic (PAL) devices. In CPLDs, configuration data may be stored on-chip in non-volatile memory. In some CPLDs, configuration data is stored on-chip in non-volatile memory, then downloaded to volatile memory as part of an initial configuration (programming) sequence.

For all of these programmable logic devices PLDs, the functionality of the device is controlled by data bits provided to the device for the purpose of configuring the device. The data bits can be stored in volatile memory (e.g., static memory cells, as in FPGAs and some CPLDs), in non-volatile memory (e.g., FLASH memory, as in some CPLDs), or in any other type of memory cell.

Other PLDs are programmed by applying a processing layer, such as a metal layer, that programmably interconnects the various elements on the device. These PLDs are known as mask programmable devices. PLDs can also be implemented in other ways, e.g., using fuse or antifuse technology. The terms “PLD” and “programmable logic device” include, but are not limited to, these exemplary devices, as well as encompassing devices that are only partially programmable. For example, some types of PLD include a combination of hard-coded transistor logic and a programmable switch fabric that programmably interconnects the hard-coded transistor logic.

The present embodiments may be implemented as fixed hardware or in the form of a PLD, for example as elements of an FPGA that are configured to take the form of a circuit. As noted above, an FPGA is a device that provides reconfigurable circuitry, for example in the form of configurable logic blocks and configurable interconnects. The logic blocks may include LUTs that provide arbitrary logic operations with rapid execution.

A circuit design may be specified using a hardware description language (HDL), such as Verilog or VHDL. The HDL uses human-readable instructions in a source file to define functional relationships between components of a circuit. The HDL source file for the circuit may then be synthesized to generate a set of circuit components. In the context of FPGAs, synthesis may include identifying sets of circuit components to implement the user-specified functions. In some cases, this may include combining multiple user-specified operations into a single logic block or cell. Thus, as described herein, multiple different operations may be automatically combined into a single configurable cell. Mapping is then performed, taking the results of the synthesis and mapping circuit components onto available parts of the FPGA hardware. Routing is performed to establish connections between the components of the FPGA hardware. This process generates a set of instructions for the FPGA, sometimes called a bitfile or bitstream, which the FPGA loads upon initialization to implement the circuit.

As a result, circuits may be embodied in fixed hardware, in a configured FPGA, or in a set of instructions that may be used to configure an FPGA. For example, such instructions may include an HDL source file that specifies circuit components and functions in a human-readable format. In another example, such a definition include a bitfile that provides machine-readable instructions to the FPGA hardware to implement the circuit. Such instructions may therefore be encoded in a non-transitory medium which, when read and executed by FPGA hardware, cause the FPGA hardware to initialize the circuit.

Embodiments may include circuit definition instructions that are accessible from a computer-usable or machine-readable medium providing hardware definition code for use by or in connection with an FPGA. A computer-usable or machine-readable medium may include any apparatus that stores, communicates, propagates, or transports the program for use by or in connection with the instruction execution system, apparatus, or device. The medium can be magnetic, optical, electronic, electromagnetic, infrared, or semiconductor system (or apparatus or device) or a propagation medium. The medium may include a machine-readable storage medium such as a semiconductor or solid state memory, a removable memory device, a random access memory (RAM), a read-only memory (ROM), a flash memory, a rigid magnetic disk, an optical disk, etc.

The circuit definition instructions may be tangibly stored in a machine-readable storage media or device (e.g., flash memory or magnetic disk) readable by a general or special purpose programmable computer or by an FPGA, for setting the hardware configuration of the FPGA when the storage media or device is executed. Embodiments may also be considered to be embodied in a machine-readable storage medium, configured with a computer program, where the storage medium so configured causes an FPGA to implement one or more circuits described herein.

A data processing system suitable for storing and/or executing circuit definition instructions may include at least one processor coupled directly or indirectly to memory elements through a system bus. The memory elements can include local memory employed during compilation of the circuit definition instructions and initialization of associated circuits, bulk storage, and cache memories. Input/output or I/O devices (including but not limited to keyboards, displays, pointing devices, etc.) may be coupled to the system either directly or through intervening I/O controllers. Network adapters may also be coupled to the system enable transmission of circuit program instructions to an FPGA device. Modems, cable modem and Ethernet cards are just a few of the currently available types of network adapters.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

As used herein, the term “direct” or “directly,” in reference to a connection between two circuit components, refers to a connection that includes only a transmission line or interconnect, without any other active or passive circuit components in the connection between the two circuit components.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

Having described preferred embodiments of adjustable clock phase for peak-current reduction (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A circuit device, comprising:
a first logic block; and
a routing block that routes a clock signal to the first logic block, the routing block including a selectable delay circuit with a plurality of delay paths and a multiplexer that selects one of the plurality of delay paths, wherein each of the plurality of delay paths delays the clock signal by a different amount.

2. The circuit device of claim 1, further comprising a configuration memory that outputs a selection signal to the multiplexer to determine which of the plurality of delay paths is selected by the multiplexer.

3. The circuit device of claim 1, wherein a first delay path of the plurality of delay paths includes a first delay stage and wherein a second delay path of the plurality of delay paths includes the first delay stage and a second delay stage.

4. The circuit device of claim 3, wherein the first delay stage and the second delay stage each include pairs of inverters.

5. The circuit device of claim 1, further comprising a second logic block that outputs a data signal to an input of the first logic block to form a hold time critical data path.

6. The circuit device of claim 5, wherein the selected one of the plurality of delay paths has a shorter delay time than a clock delay path of the second logic block to reduce peak power while preventing hold time violation.

7. The circuit device of claim 1, further comprising a second logic block that outputs a data signal to an input of the first logic block to form a critical net long data path.

8. The circuit device of claim 7, wherein the selected one of the plurality delay paths has a longer delay time than a clock delay path of the second logic block to reduce peak power while preventing setup time violation.

9. A configurable circuit product, the configurable circuit product having a non-transitory machine-readable storage medium that stores circuit configuration instructions, the circuit configuration instructions being readable by a field programmable gate array device to initialize a circuit that comprises:
a first logic block; and
a routing block that routes a clock signal to the first logic block, the routing block including a selectable delay circuit with a plurality of delay paths and a multiplexer that selects one of the plurality of delay paths, wherein each of the plurality of delay paths delays the clock signal by a different amount.

10. The configurable circuit product of claim 9, wherein the circuit further comprises a configuration memory that outputs a selection signal to the multiplexer to determine which of the plurality of delay paths is selected by the multiplexer.

11. The configurable circuit product of claim 9, wherein a first delay path of the plurality of delay paths includes a first delay stage and wherein a second delay path of the plurality of delay paths includes the first delay stage and a second delay stage.

12. The configurable circuit product of claim 9, wherein the circuit further comprises a second logic block that outputs a data signal to an input of the first logic block to form a hold time critical data path.

13. The configurable circuit product of claim 12, wherein the selected one of the plurality of delay paths has a shorter delay time than a clock delay path of the second logic block to reduce peak power while preventing hold time violation.

14. The configurable circuit product of claim 9, wherein the circuit further comprises a second logic block that outputs a data signal to an input of the first logic block to form a critical net long data path.

15. The configurable circuit product of claim 14, wherein the selected one of the plurality delay paths has a longer delay time than a clock delay path of the second logic block to reduce peak power while preventing setup time violation.

16. A method for configuring a circuit device, comprising:
placing and routing circuit design components, including a first logic block, a second logic block, wherein the first logic block and the second logic block each receive a clock signal;
selecting a first phase delay path for the clock signal to the first logic block and a second phase delay path for the clock signal to the second logic block, the first phase delay path and the second phase delay path having different delay times, to cause the first logic block and the second logic block to trigger out of phase.

17. The method of claim 16, further comprising identifying a critical timing data path from the first logic block to the second logic block and changing the selected first phase delay path and the selected second phase delay path responsive to the identified critical timing path.

18. The method of claim 17, wherein the critical timing data path includes a critical hold time path and the first phase delay path is changed to have a longer delay time than the second phase delay path.

19. The method of claim 17, wherein the critical timing data path includes a critical setup time path and the first phase delay path is changed to have a shorter delay time than the second phase delay path.

20. The method of claim 17, wherein the critical timing data path includes a critical net long data path and the first phase delay path is changed to have a shorter delay time than the second phase delay path.
